(19) United States
(12) Patent Application Publication
(10) Pub. No.: US 2008/0135215 A1
(43) Pub. Date: Jun. 12, 2008

(54) HEAT DISSIPATION DEVICE

(75) Inventor: YI-QIANG WU, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Taipei Hsien (TW)

(21) Appl. No.: 11/567,598

(22) Filed: Dec. 6, 2006

(51) Int. Cl. H05K 7/20

(52) U.S. Cl. 165/104.33; 165/80.3; 361/700

(57) ABSTRACT

A heat dissipation device includes a heat sink including a base and a plurality of fins on the base. Each of the fins includes a body stamped with at least a flap toward an adjacent fin. A plurality of passages is defined between adjacent fins. A fan is attached to the heat sink for providing forced airflow to the heat sink. The at least a flap of the body of each of the fins leans from the fan toward a heat-accumulating portion of the heat sink to guide a stream of the airflow from the fan to the heat-accumulating portion of the heat sink. The heat-accumulating portion is either a connecting portion between the fins and heat pipes, or the base of the heat sink.

### BACKGROUND OF THE INVENTION

1. Field of the Invention

The present invention relates generally to a heat dissipation device, and more particularly to a heat dissipation device used for dissipating heat generated by an electronic device.

2. Description of Related Art

With advancement of computer technology, electronic devices are operating at ever higher speeds. It is well known that the more rapidly the electronic devices operate, the more heat they generate. If the heat is not dissipated, the stability of the operation of the electronic devices will be impacted severely. Generally, in order for the electronic device to run normally a heat dissipation device is used to dissipate the heat generated by the electronic device.

Conventionally, a heat dissipation device comprises a heat sink which has a base and a plurality of fins mounted on the base. The fins are oriented parallel to each other and arranged on the base with spaces between adjacent fins. Therefore, pluralities of passages are defined between the fins to allow airflow to pass therethrough. Usually the heat dissipation device further comprises a fan located aside the heat sink for providing forced airflow to the heat sink. The heat generated by the electronic device accumulates on the base. Sometimes a heat pipe is used for transferring the heat from the base to the fins. In the conventional design, there is insufficient airflow from the fan of the heat dissipation device can be distributed to the base or the heat pipe to duly remove the heat accumulated therein. Heat dissipation capacity of the heat dissipation device cannot meet heat dissipation requirements for the up-to-date electronic devices. Consequently, in order to improve the heat dissipation capacity, the heat dissipation device needs to be improved.

What is needed, therefore, is a heat dissipation device having greater heat dissipation capacity.

### SUMMARY OF THE INVENTION

A heat dissipation device in accordance with a preferred embodiment of the present invention is used for dissipating heat generated by an electronic device. The heat dissipation device comprises a heat sink comprising a base and a plurality of fins on the base. Each of the fins comprises a body stamped with at least a flap toward an adjacent fin. A plurality of passages is defined with one between each fin and its adjacent fin. A fan is attached to the heat sink for providing forced airflow to the heat sink. The at least a flap of the body of each of the fins leans from the fan toward a heat-accumulating portion of the heat sink to guide a stream of airflow from the fan to the heat-accumulating portion of the heat sink. The heat-accumulating portion according to the preferred embodiment is a connecting portion between heat pipes and the fins of the heat sink. The heat-accumulating portion according to another embodiment is the base of the heat sink.

Other advantages and novel features of the present invention will become more apparent from the following detailed description when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an exploded, isometric view of a heat dissipation device in accordance with a preferred embodiment of the present invention;

FIG. 2 shows a fin set of the heat dissipation device of FIG. 1;

FIG. 3 is an assembled view of FIG. 1;

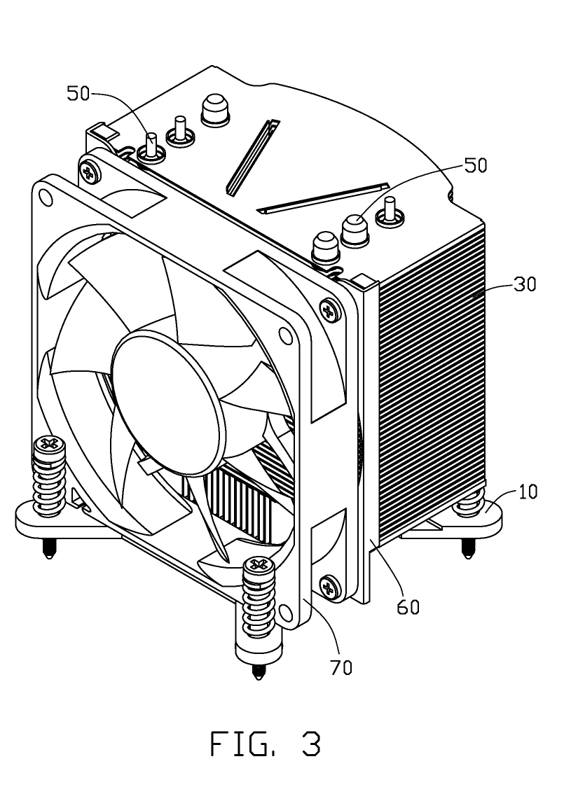

FIG. 4 is a plan view of FIG. 3;

FIG. 5 is an exploded, isometric view of a heat dissipation device in accordance with an alternative embodiment of the present invention;

FIG. 6 shows a fin set of the heat dissipation device of FIG. 5;

FIG. 7 is an assembled view of FIG. 5; and

FIG. 8 is a side view of FIG. 7.

### DETAILED DESCRIPTION OF THE INVENTION

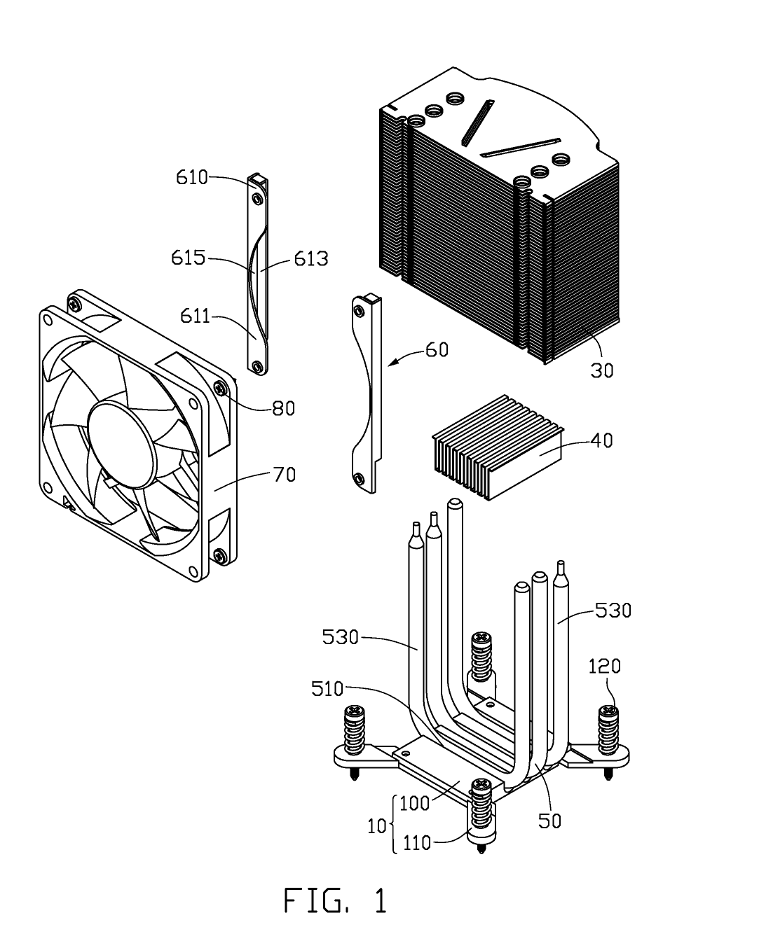

Referring to FIG. 1, a heat dissipation device in accordance with a preferred embodiment of the present invention comprises a heat sink (not labeled) having a base 10 and a fin set 30 on the base 10, three heat pipes 50 connecting the base 10 and the fin set 30 for transferring heat from the base 10 to the fin set 30, and a fan 70 attached to a side of the fin set 30 by a fan holder 60.

The base 10 comprises a substantially rectangular heat receiver 100, and four fixing legs 110 extending outwardly from four corners of the heat receiver 100. The heat receiver 100 is made from a highly heat conductive metal such as copper, aluminum or the like. A top face of the heat receiver 100 defines three parallel grooves (not labeled) therein. A bottom face of the heat receiver 100 is flat for thermally contacting a heat generating electronic device. Each of the fixing legs 110 defines a fixing hole (not labeled) adjacent to a distal end thereof for fixing the heat dissipation device to a printed circuit board (not shown) by a fastener 120 engaging in the fixing hole.

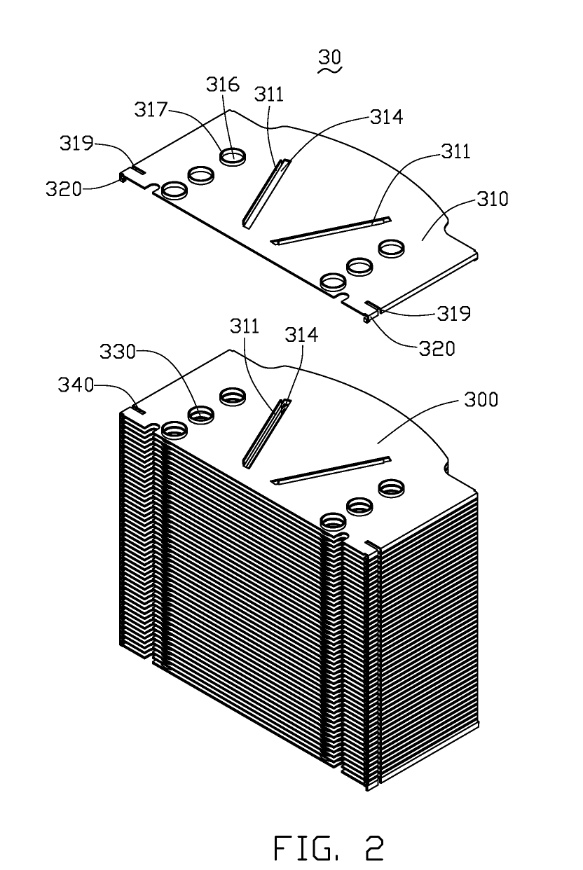

Referring also to FIG. 2, the fin set 30 comprises a plurality of fins 300 assembled together. Each fin 300 comprises a main body 310, two flanges 320 perpendicularly extending from two opposite lateral edges of the main body 310. The main body 310 has a linear front edge (not labeled) perpendicular to the flanges 320 and an opposite curved rear edge (not labeled) projecting rearwards beyond the flanges 320. Two spaced flaps 311 are stamped from the main body 310, leaving two slits 314 between the two flaps 311 in the main body 310 of the fin 300. Each flap 311 is oriented substantially perpendicular to the main body 310 and has a height equal to or less than that of the flange 320. Each of the two flaps 311 has a first end adjacent to the linear front edge of the main body 310 and a second end extending toward the curved rear edge of the main body 310. The two flaps 311 have the first ends thereof adjacent to each other and the second ends apart from each other, thereby defining a wedge-shaped portion in a middle portion of the main body 310. Two rows of through holes 316 are defined outside corresponding flaps 311 in the main body 310. Each hole 316 is circumferentially surrounded by a collar 317 extending upwardly from the main body 310. The main body 310 defines two short slots 319 parallel and adjacent to the linear front edge. The flanges 320 of the each fin 300 of the fin set 30 abut the main body 310 of an adjacent fin 300 of the fin set 30. The flaps 311 of each fin 300 of the fin set 30 extend to the main body 310 of the adjacent fin 300 of the fin set 30. The through holes 316 of the fins 300 of the fin set 30 cooperatively define three channels 330 outside the flaps 311 of the fin set 30 for receiving the heat pipes 50 therein. Corresponding slots 319 of the fins 300 of the fin set 30 cooperatively define a groove 340 for fixing the fan holder 60. A plurality of passages (not labeled) is defined between adjacent fins 300 of the fin set 30.

Referring again to FIG. 1, each heat pipe 50 comprises a first section 510 and two parallel second sections 530 perpendicularly extending from two ends of the first section 510. A rounder corner (not labeled) is formed at each joint of the first section 510 and the second sections 530. The first section 510 is received in a corresponding groove of the base 10. The second section 530 extends beyond the base 10 and is thermally received in a corresponding channel 330 of the fin set 30. Therefore, the fin set 30 is stacked on the second sections 530 of the heat pipes 50 with the second sections 530 of the heat pipes 50 being located outside the flaps 311 and closer and closer to the flaps 311 along the front-to-rear direction of the fin set 30. In other words, the flaps 311 lean toward the second sections 530 of the heat pipes 50.

The heat dissipation device further comprises a fin unit 40 located between the base 10 and the fin set 30. The fin unit 40 is folded from a piece of metal sheet, and has a bottom face thermally contacting the top face of the base 10 and a top face contacting a bottom face of the fin set 30. The fin set 30 is stacked on the second sections 530 of the heat pipes 50, and is further supported by the fin unit 40.

The fan holder 60 comprises two spaced brackets 610. Each bracket 610 comprises a fixing face 611, a positioning rib 613 substantially parallel to the fixing face 611, and a connecting rib 615 connecting the fixing face 611 and the positioning rib 613. The positioning ribs 613 of the fan holder 60 engage in corresponding grooves 340 of the fin set 30, thereby attaching the fan holder 60 to the fin set 30. The fixing faces 611 are located on a front side of the fin set 30 and mount the fan 70 thereon via a plurality of fasteners such as screws 80. By this, the fan 70 confronts to the passages of the fin set 30 and adjacent to the first ends of the two flaps 311, therefore, more airflow produced by the fan 70 can be guided to the heat pipes 50 by the flaps 311 of the fin set 30.

In use, the base 10 the bottom face contacts the electronic device and absorbs heat from the electronic device. Part of the heat in the base 10 is transferred to the fin unit 40, and part of the heat is absorbed by the first sections 510 of the heat pipes 50. Subsequently, the heat in heat pipes 50 is transferred to the fins 300 of the fin set 30 by the second sections 530 of the heat pipes 50. The heat in the fin set 30, the fin unit 40 and the heat pipes 50 is duly dissipated to ambient air by the fan 70.

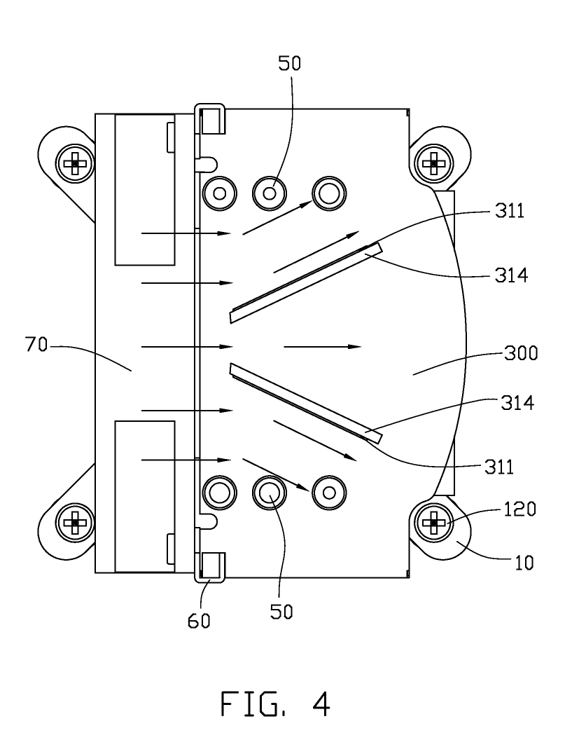

According to the heat dissipation device of the preferred embodiment of the present invention, each fin 300 of the fin set 30 of the heat dissipation device has two flaps 311 leaning toward the second sections 530 of the heat pipes 50; therefore, more airflow from the fan 70 is guided to the second sections 530 of the heat pipes 50 and portions of the fins 300 around the second sections 530 of the heat pipes 50 by the flaps 311, as shown in FIG. 4. As a result, more heat in the second sections 530 of the heat pipes 50 and the portions of the fins 300 around the second sections 530 is dissipated to ambient air by the airflow, thus avoiding overheating of heat dissipation device. So, heat dissipation capacity of the heat dissipation device of the present invention is improved in comparison with the heat dissipation devices in the related art.

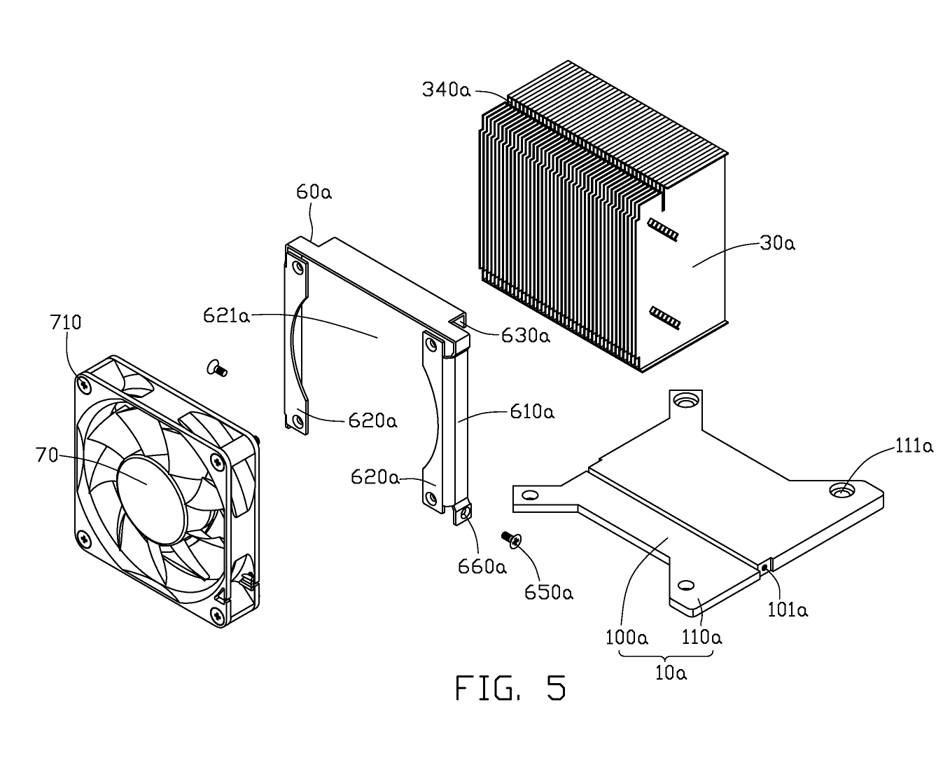

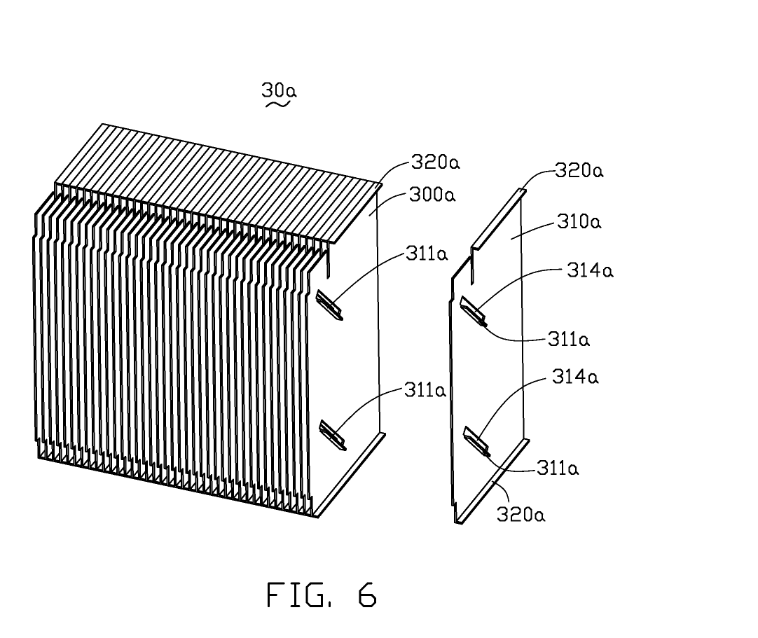

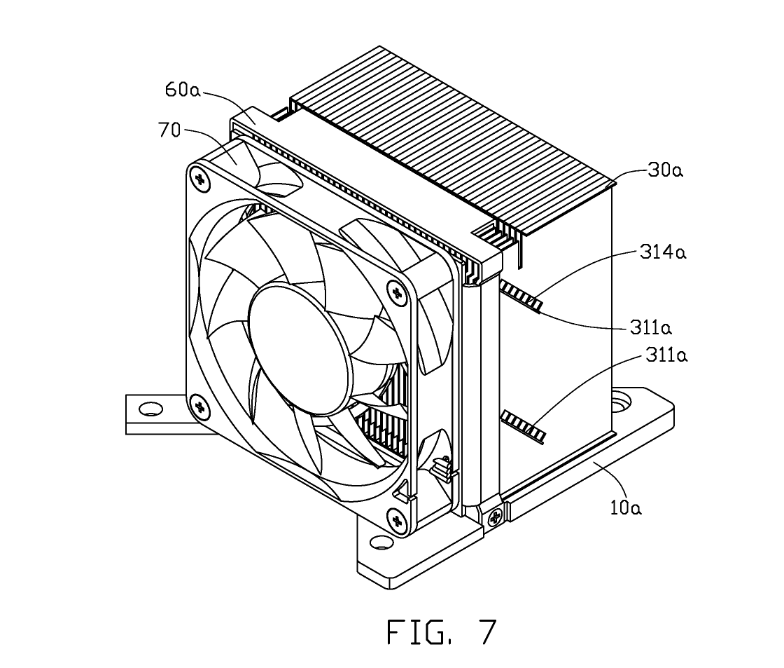

Referring to FIGS. 4-8, a heat dissipation device in accordance with an alternative embodiment of the present invention is shown. The heat dissipation device comprises a base 10a, a fin set 30a located on the base 10a, and a fan 70 attached to the fin set 30a by a fan holder 60a.

The base 10a comprises a substantially rectangular heat receiver 100a, and four fixing legs 110a integrally extending outwardly from four corners of the heat receiver 100a. Two opposite lateral faces of the heat receiver 100a define two opposite fixing apertures 101a for fixing the fan holder 60a thereto. Each fixing legs 110a defines a fixing hole 111a adjacent to a distal end thereof for accommodating a fastener (not shown) to fasten the heat dissipation device to the printed circuit board.

The fin set 30a comprises a plurality of fins 300a each having bottom and top flanges 320a which are substantially perpendicularly extended from a body 310a of each fin 300a. The fin set 30a has a top face defining a slot 340 therein for positioning the fan holder 60a on the fin set 30a. The bottom flanges 320a of the fins 300a of the fin set 30a cooperatively form a face thermally contacting a top face of the base 10a. Two parallel flaps 311a are stamped at an angle from the body 310a of each fin 300a, thereby leaving two parallel slits 314a in the body 310a. The flaps 311a are substantially perpendicular to the body 310a. A height of each flap 311a from the body 310a is substantially equal to or less than that of the flange 320a. Each flap 311 extends along top left-bottom right direction in the body 310a of the fin set 30a, that is to say each flap 311 extends toward the base 10a. In other words, each flap 311 has a rear end pointing toward the base 10a.

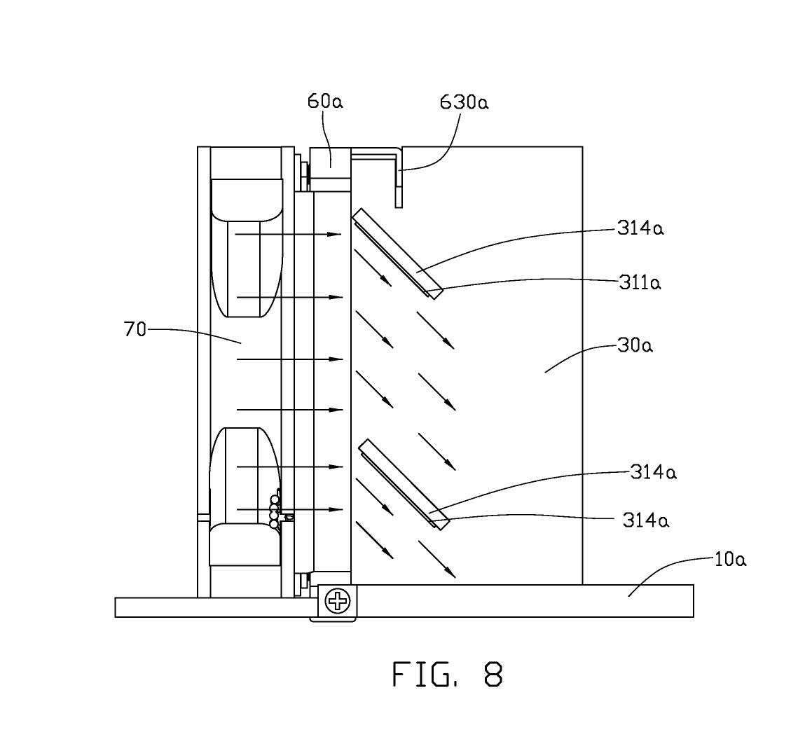

The fan holder 60a comprises a U-shaped frame 610a and two opposite faceplates 620a extending from two lateral sides of the frame 610a. The frame 610a extends a positioning rib 630a from a top side thereof. An opening 621a is surrounded by the top side of the frame 610a and the two faceplates 620a. The positioning rib 630a engages in the slot 340a of the fin set 30a. The two lateral sides of the frame 610a have distal bottom ends being fixed to the base 10a via bolts 650a engaging through holes 660a defined therein and corresponding fixing apertures 101a of the base 10a; in this manner the fan holder 60a is fixed to the fin set 30a. The fan 70 is attached to the faceplates 620a by a plurality of screws 710. As a result the flaps 311a of the fin set 30a have front ends thereof adjacent to the fan 70, and rear ends thereof leaning towards the base 10a, thereby guiding more airflow produced by the fan 70 to the base 10a to remove more heat in the base 10a, as shown in FIG. 8.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device for dissipating heat generated by an electronic device, the heat dissipation device comprising:
a heat sink including a fin set comprising a plurality of fins, each fin having a body having at least a flap at a side of the body; and
a fan attached to the heat sink for providing airflow to the heat sink;
wherein the at least a flap of the fin set is arranged so as to guide a stream of the airflow from the fan to at least a portion of the heat sink where heat from the electronic device accumulates.

2. The heat dissipation device of claim 1, wherein the heat sink comprises a base for absorbing heat from the electronic device, the fin set being on the base.

3. The heat dissipation device of claim 2, wherein the heat sink further comprises at least a heat pipe connecting the base and the fin set for transferring heat from the base to the fin set.

4. The heat dissipation device of claim 3, wherein the at least a heat pipe comprises a first section thermally contacting the base and at least a second section extending from the first section and through each of the fins of the fin set.

5. The heat dissipation device of claim 4, wherein the at least a flap of each of the fins of the fin set of the heat sink leans from the fan toward the at least a second section of the at least a heat pipe, thereby guiding the stream of the airflow from the fan to the at least a second section of the at least a heat pipe.

6. The heat dissipation device of claim 4, wherein the at least a heat pipe comprises two second sections extending from two ends of the first section thereof, the fin set being stacked on the second sections of the at least a heat pipe.

7. The heat dissipation device of claim 6, wherein the body of each of the fins of the fin set comprises two symmetrical flaps lean toward corresponding second sections of the at least a heat pipe.

8. The heat dissipation device of claim 7, wherein the body of each of the fins of the fin set defines a wedge-shaped portion between the two flaps thereof.

9. The heat dissipation device of claim 8, wherein the two second sections of the at least a heat pipe are located at two sides of the wedge-shaped portions of the bodies of the fins of the fin set, respectively.

10. The heat dissipation device of claim 2, wherein the fin set has a bottom face thermally contacting the base, wherein the at least a flap of the body of each of the fins of the fin set leans from the fan toward the base to guide the stream of the airflow from the fan to the base.

11. The heat dissipation device of claim 10, wherein the body of each of the fins of the fin set includes two parallel flaps leaning toward the base.

12. The heat dissipation device of claim 1, wherein the fan is attached to the heat sink by a fan holder, the fan holder comprises a faceplate mounting the fan thereon and a positioning rib engaging in a slot defined in the fin set.

13. A heat dissipation device used for dissipating heat generated by an electronic device, the heat dissipation device comprising:
a heat sink comprising a base and a plurality of fins on the base, each of the fins comprising a body having at least a flap toward an adjacent one of the fins, a plurality of passages being defined between adjacent ones of the fins; and
a fan attached to the heat sink for providing forced airflow to the heat sink;
wherein the at least a flap of the body of each of the fins leans from the fan toward a heat-accumulating portion of the heat sink to guide a stream of the airflow from the fan to the heat-accumulating portion of the heat sink.

14. The heat dissipation device of claim 13, wherein the at least a flap of the body of each of the fins of the heat sink leans from the fan toward the base of the heat sink for guiding a stream of the airflow from the fan to the base.

15. The heat dissipation device of claim 13, wherein the heat sink comprises at least a heat pipe having a first section thermally contacting the base and at least a second section remote from the base and extending through the fins thereof, the at least a flap of the body of each of the fins of the heat sink leaning from the fan toward the at least a second section of the at least a heat pipe.

16. The heat dissipation device of claim 15, wherein the at least a heat pipe comprises two second sections extending from two ends of the first section thereof, the body of each of the fins of the heat sink comprising the two flaps leaning toward corresponding second sections of the at least a heat pipe.

17. A heat dissipation device comprising:
a heat sink comprising a base adapted for thermally connecting with a heat-generating electronic component and a plurality of fins on the base, wherein each of the fins comprises a flap thereon; and
a fan for generating an airflow through the fins of the heat sink; wherein the flaps guide a stream of the airflow to a part of the heat sink at which heat accumulates.

18. The heat dissipation device of claim 17, wherein the heat sink has a heat pipe thermally connecting the base and the fins, and the heat-accumulating part of the heat sink is a connecting portion between the heat pipe and fins.

19. The heat dissipation device of claim 18, wherein the flap has a first end adjacent to the fan and a second end remote from the fan, and the flap extends from the first end to the second end along a direction toward the connecting portion between the heat pipe and the fins.

20. The heat dissipation device of claim 17, wherein the heat-accumulating part of the heat sink is the base of the heat sink.
